(19) United States
(12) Patent Application Publication
(10) Pub. No.: US 2025/0109353 A1
(43) Pub. Date: Apr. 3, 2025

(54) POST-CHEMICAL MECHANICAL POLISHING CLEANING COMPOSITION, POST-CHEMICAL MECHANICAL POLISHING CLEANING METHOD, AND METHOD FOR PRODUCING SEMICONDUCTOR SUBSTRATE

(71) Applicant: FUJIMI INCORPORATED, Aichi (JP)

(72) Inventors: Takahiro ITO, Aichi (JP); Natsuko OSHIMA, Aichi (JP); Tsutomu YOSHINO, Aichi (JP)

(21) Appl. No.: 18/894,197

(22) Filed: Sep. 24, 2024

(30) Foreign Application Priority Data
Sep. 28, 2023 (JP) 2023-167704
Jul. 16, 2024 (JP) 2024-113369

(51) Int. Cl. C11D 1/00; H01L 21/321

(52) U.S. Cl. CPC C11D 1/008; H01L 21/3212; C11D 2111/22

(57) ABSTRACT

An object of the present invention is to provide a means capable of sufficiently removing residues remaining on the surface of a polished object to be polished containing a silicon-containing material.

The present invention is a post-chemical mechanical polishing cleaning composition containing a nitrogen-containing nonionic polymer and an anionic polymer containing a sulfonic acid group, in which the content of the nitrogen-containing nonionic polymer is more than 0.1% by mass and less than 1.0% by mass with respect to the entire post-chemical mechanical polishing cleaning composition, and the pH is less than 7.0.

### CROSS-REFERENCE TO RELATED APPLICATION

The present application is based on Japanese Patent Application No. 2023-167704 filed on Sep. 28, 2023 and Japanese Patent Application No. 2024-113369 filed on Jul. 16, 2024, the disclosures of which are incorporated herein by reference in their entireties.

### BACKGROUND

### 1. Technical Field

The present invention relates to a post-chemical mechanical polishing cleaning composition, a post-chemical mechanical polishing cleaning method, and a method for producing a semiconductor substrate.

### 2. Description of Related Arts

In recent years, along with multilayer wiring on a surface of a semiconductor substrate, a semiconductor substrate is physically polished and planarized, that is, so-called chemical mechanical polishing (CMP) technology is utilized when manufacturing a device. CMP is a method for planarizing a surface of an object to be polished (object that will be polished) such as a semiconductor substrate using a polishing composition (slurry) containing an abrasive such as silica, alumina, and ceria, an anticorrosive agent, a surfactant, and the like, and the object to be polished (object that will be polished) is wiring, a plug, or the like made of a silicon-containing material, for example, silicon, polysilicon, silicon oxide, and silicon nitride, and a metal, and the like.

A large amount of impurities (also referred to as foreign matters or residues) remain on the surface of the semiconductor substrate after the CMP step. The impurities include an abrasive derived from the polishing composition used in CMP, metals, anticorrosive agents, organic substances such as surfactants, silicon-containing materials which are objects to be polished, silicon-containing materials and metals generated by polishing metal wirings, plugs, and the like, and organic substances such as pad debris generated from various pads and the like.

If the surface of the semiconductor substrate is contaminated with these impurities, the electrical characteristics of the semiconductor are adversely affected, and the reliability of the device may be reduced. Therefore, it is desirable to introduce a cleaning step after the CMP step to remove these impurities from the surface of the semiconductor substrate.

As such a cleaning composition, for example, JP 2020-167237A discloses a rinse composition for a silicon wafer, containing a water-soluble polymer satisfying a specific condition, and it is disclosed that it is possible to remove foreign matters of the silicon wafer after polishing and reduce defects of the silicon wafer after polishing.

### SUMMARY

However, the technique of JP 2020-167237A is problematic in that foreign matters (residues) may not be sufficiently removed in cleaning a polished object to be polished containing a silicon-containing material.

Therefore, an object of the present invention is to provide a means capable of sufficiently removing residues remaining on the surface of a polished object to be polished containing a silicon-containing material.

The present inventors have performed intensive investigations in view of the above problems. As a result, the present inventors have found that the above problems may be solved by a post-chemical mechanical polishing cleaning composition containing a nitrogen-containing nonionic polymer and an anionic polymer containing a sulfonic acid group, wherein a content of the nitrogen-containing nonionic polymer is more than 0.1% by mass and less than 1.0% by mass with respect to the entire post-chemical mechanical polishing cleaning composition, and a pH is less than 7.0, and have completed the present invention.)

### DETAILED DESCRIPTION

The present invention is a post-chemical mechanical polishing cleaning composition containing a nitrogen-containing nonionic polymer and an anionic polymer containing a sulfonic acid group, wherein a content of the nitrogen-containing nonionic polymer is more than 0.1% by mass and less than 1.0% by mass with respect to the entire post-chemical mechanical polishing cleaning composition, and a pH is less than 7.0.

In the present description, the post-chemical mechanical polishing cleaning composition having the above configuration is hereinafter also referred to as “post-chemical mechanical polishing cleaning composition according to the present invention”, “post-CMP cleaning composition”, or “post-CMP cleaning composition according to the present invention”.

According to the post-chemical mechanical polishing cleaning composition (post-CMP cleaning composition) according to the present invention, it is possible to sufficiently remove residues (for example, abrasive residues, in particular silicon compounds, organic residues) remaining on the surface of the polished object to be polished, particularly, the polished object to be polished containing a silicon-containing material, for example, silicon nitride, silicon oxide, and polysilicon.

In the present description, the polished object to be polished means an object to be polished after being polished with the polishing composition. In an embodiment of the present invention, the polished object to be polished contains a silicon-containing material. The polished object to be polished containing silicon nitride means that the polished object to be polished has a film (layer) containing silicon nitride, the polished object to be polished containing silicon oxide means that the polished object to be polished has a film (layer) containing silicon oxide, and the polished object to be polished containing polysilicon means that the polished object to be polished has a film (layer) containing polysilicon. That is, the polished object to be polished according to an embodiment of the present invention contains a silicon-containing material, for example, at least one type selected from the group consisting of silicon nitride, silicon oxide, and polysilicon. Hereinafter, a “polished object to be polished containing a silicon-containing material” may be simply referred to as a “polished object to be polished”.

The present inventors presume a mechanism by which residues on the surface of the polished object to be polished can be removed by the above configuration as follows.

That is, the components contained in the post-CMP cleaning composition act on the surface of the polished object to be polished, thereby removing the residue from the surface of the polished object to be polished. Specifically, the nitrogen-containing nonionic polymer and the anionic polymer containing a sulfonic acid group are adsorbed on the surface of the polished object to be polished, whereby the residue present on the surface of the polished object to be polished can be desorbed. The present inventors have found that in the removal of these residues, the content of the nitrogen-containing nonionic polymer is more than 0.1% by mass and less than 1.0% by mass with respect to the entire post-CMP cleaning composition, and the pH is less than 7.0, whereby the residues on the surface of the polished object to be polished can be more efficiently removed. Details of these mechanisms are unknown, but the following reasons are presumed. That is, it is considered that, with the above configuration, the nitrogen-containing nonionic polymer and the anionic polymer containing a sulfonic acid group are more likely to be effectively adsorbed to the polished object to be polished, whereby the residues on the surface of the polished object to be polished can be more efficiently desorbed, and the reattachment of the residues (contaminants) to the surface of the polished object to be polished can be suppressed.

The anionic polymer containing a sulfonic acid group is easily adsorbed to the film containing silicon nitride, and the post-CMP cleaning composition of an embodiment of the present invention can suitably exhibit the above effect in the film containing silicon nitride.

In addition, the sulfonic acid group is a strongly acidic group, and thus hydrogen ions (H⁺) can be released even in a solution in which a pH value is small (for example, in a solution with a pH 2 to 4), and an ionized state (R—SO₃⁻) can be maintained. Therefore, if the post-CMP cleaning composition contains an anionic polymer containing a sulfonic acid group, a sulfonic acid group in the anionic polymer containing the sulfonic acid group is in an ionized state (R—SO₃⁻), so that the zeta potential on the surfaces of the polished object to be polished and the residue (contaminant) to which the anionic polymer containing a sulfonic acid group is adsorbed can be both controlled to be negative. As a result, an electrostatic repulsive interaction between the polished object to be polished and the residue (contaminant) is generated, and the residue (contaminant) can be efficiently desorbed from the polished object to be polished, and further can be suppressed from being reattached to the polished object to be polished. The nitrogen-containing nonionic polymer is easily adsorbed to the film containing silicon oxide and/or the film containing polysilicon, and the post-CMP cleaning composition of an embodiment of the present invention can suitably exhibit the above effect in the film containing silicon oxide and/or the film containing polysilicon. In addition, the nitrogen atom of the nitrogen-containing nonionic polymer can be particularly effectively adsorbed to the film containing silicon oxide by forming hydrogen bond with a hydroxyl group present on the surface of the film containing silicon oxide, whereby the above effect is further exhibited.

Further, with the above configuration, each component adsorbed on the surface of the polished object to be polished (nitrogen-containing nonionic polymer and anionic polymer containing a sulfonic acid group) can also be easily desorbed from the surface of the polished object to be polished, and each component itself adsorbed on the surface of the polished object to be polished can be made to hardly become a residue or not to become a residue. From the above, it is considered that the post-CMP cleaning composition of the present invention can sufficiently remove residues.

The above mechanism is based on presumption, and the present invention is not limited to the above mechanism at all.

Hereinafter, embodiments of the present invention will be described in detail, but the present invention is not limited to only the following embodiments, and various modifications can be made within the scope of claims. The embodiments described in the present description can become other embodiments by being optionally combined. In the present description, unless otherwise specified, operations and measurements of physical properties and the like are performed under conditions of room temperature (20° C. or more and 25° C. or less)/relative humidity of 40% RH or more and 50% RH or less.

### Residue

In the present description, the residue represents foreign matters attached to the surface of the polished object to be polished. Examples of the residues include, but are not particularly limited, organic residues to be described later, particle residues derived from abrasive contained in the polishing composition, residues made of components other than the particle residues and the organic residues, and other residues such as a mixture of the particle residues and the organic residues.

In the present description, the organic residues represent components made of an organic substance such as an organic low molecular weight compound or a polymer compound, an organic salt, or the like, among foreign matters attached to the surface of the polished object to be polished (object to be subjected to surface treatment).

Examples of the organic residues attaching to the polished object to be polished include pad debris generated from a pad used in the polishing step or the rinse polishing step described later, and components derived from additives contained in the polishing composition used in the polishing step or the post-CMP cleaning composition used in the rinse polishing step.

The organic residues and other foreign matters are greatly different in color and shape, and thus it is possible to visually determine whether or not the foreign matter is an organic residue by SEM observation. In addition, whether or not the foreign matters are organic residues may be determined by element analysis using an energy dispersive X-ray analyzer (EDX) as necessary. The number of organic residues can be measured using a wafer defect inspection apparatus and SEM or EDX elemental analysis.

### Polished Object to be Polished

In the present description, the polished object to be polished means an object to be polished after being polished in the polishing step. The polishing step is a CMP step.

The polished object to be polished (object to be polished) according to an embodiment of the present invention contains a silicon-containing material, for example, silicon nitride (Si₃N₄), silicon oxide (SiO₂), and polysilicon (polycrystalline silicon). In one embodiment, the polished object to be polished (object to be polished) according to the present invention contains at least one type selected from the group consisting of silicon nitride (Si₃N₄), silicon oxide (SiO₂), and polysilicon (polycrystalline silicon).

The material contained in the object to be polished according to an embodiment of the present invention is not particularly limited as long as it contains a silicon-containing material, for example, at least one type selected from the group consisting of silicon nitride (Si₃N₄), silicon oxide (SiO₂), and polysilicon (polycrystalline silicon), and may further contain, for example, carbon-containing silicon such as silicon carbonitride (SiCN), amorphous silicon, a silicon material doped with impurities, a simple substance metal, an alloy, a metal nitride, a compound semiconductor such as SiGe, and the like.

Examples of the film containing silicon oxide include a TEOS (tetraethyl orthosilicate) silicon oxide film (hereinafter, also simply referred to as “TEOS film”) produced using tetraethyl orthosilicate as a precursor, an HDP (high density plasma) film, a USG (undoped silicate glass) film, a PSG (phosphorus silicate glass) film, a BPSG (boron-phospho silicate glass) film, and an RTO (rapid thermal oxidation) film. The film containing silicon oxide contained in the polished object to be polished may be one type singly or a combination of two or more types.

The polished object to be polished is a polished semiconductor substrate, and is preferably a semiconductor substrate after the CMP step. This is because the residue can cause destruction of the semiconductor device, and thus, if the polished object to be polished is a polished semiconductor substrate, it is necessary that the residue can be removed as much as possible as a step of cleaning the semiconductor substrate.

In addition, the post-CMP cleaning composition according to one aspect of the present invention can reduce residues on the surface even in a polished object to be polished including both a hydrophilic material and a hydrophobic material. Herein, the hydrophilic material refers to a material in which a contact angle with water is less than 50°, and the hydrophobic material refers to a material in which a contact angle with water is 50° or more. The contact angle with water is a value measured by a contact angle meter DropMaster (DMo-501) manufactured by Kyowa Interface Science Co., Ltd.

Specific examples of the hydrophilic material include silicon oxide, silicon nitride, silicon oxynitride, tungsten, titanium nitride, tantalum nitride, and boron-containing silicon. These hydrophilic materials may be used singly or in combination of two or more types thereof.

According to a preferable embodiment of the present invention, the hydrophilic material is silicon nitride. According to a preferable embodiment of the present invention, the hydrophilic material is silicon nitride and silicon oxide. Specific examples of the hydrophobic material include polysilicon (polycrystalline silicon), monocrystalline silicon, amorphous silicon, and carbon-containing silicon. These hydrophobic materials may be used singly or in combination of two or more types thereof. According to a preferable embodiment of the invention, the hydrophobic material is polysilicon (polycrystalline silicon).

That is, according to a preferable embodiment of the present invention, the hydrophilic material is silicon nitride, and the hydrophobic material is polysilicon (polycrystalline silicon). In addition, according to a preferable embodiment of the present invention, the hydrophilic material is silicon nitride and silicon oxide, and the hydrophobic material is polysilicon (polycrystalline silicon).

### Post-Chemical Mechanical Polishing Cleaning Composition (Post-CMP Cleaning Composition)

The post-chemical mechanical polishing cleaning composition (post-CMP cleaning composition) according to the present invention contains a nitrogen-containing nonionic polymer and an anionic polymer containing a sulfonic acid group. Herein, in the present description, the “polymer” means a compound in which a weight-average molecular weight (Mw) is 1000 or more. In the present description, the term “nonionic polymer” refers to a polymer having no anionic group such as a carboxylic acid group, a sulfonic acid group, or a phosphoric acid group, and no cationic group such as an amino group or a quaternary ammonium group in the molecule. The “anionic polymer” refers to a polymer having an anionic group such as a carboxylic acid group, a sulfonic acid group, or a phosphoric acid group in the molecule. Hereinafter, each polymer will be described.

### Nitrogen-Containing Nonionic Polymer

The nitrogen-containing nonionic polymer contained in the post-CMP cleaning composition according to the present invention refers to a polymer containing a nitrogen atom in the molecule among the nonionic polymers.

The weight-average molecular weight of the nitrogen-containing nonionic polymer is preferably 1,500 or more, more preferably 3,000 or more, still more preferably 5,000 or more, yet still more preferably 10,000 or more, particularly preferably 25,000 or more, and most preferably 35,000 or more. In addition, the weight-average molecular weight of the nitrogen-containing nonionic polymer is preferably 1,000,000 or less, more preferably 500,000 or less, still more preferably 300,000 or less, yet still more preferably 100,000 or less, particularly preferably 80,000 or less, and most preferably 60,000 or less. That is, the weight-average molecular weight of the nitrogen-containing nonionic polymer is preferably 1,500 or more and 1,000,000 or less, more preferably 3,000 or more and 500,000 or less, still more preferably 5,000 or more and 300,000 or less, yet still more preferably 10,000 or more and 100,000 or less, particularly preferably 25,000 or more and 80,000 or less, and most preferably 35,000 or more and 60,000 or less. If the weight-average molecular weight of the nitrogen-containing nonionic polymer is within the above range, residues on the surface of the polished object to be polished can be more efficiently removed after the treatment using the post-CMP cleaning composition, and the desired effect of the present invention is more exhibited.

The nitrogen-containing nonionic polymer is not limited as long as it is a nonionic polymer having a nitrogen atom, and examples thereof include polyamines, polyvinylpyrrolidone, polyacrylamide, poly-N-vinylacetamide, polydimethylacrylamide, polyacryloylmorpholine, poly-N-vinylcaprolactam, poly-N-isopropylacrylamide, and oxazoline group-containing polymers. As the nitrogen-containing nonionic polymer, not only a polymer having a main chain structure as described above but also a graft copolymer having a nonionic polymer structure in a side chain can be suitably used. The nitrogen-containing nonionic polymer may be a polymer having the same repeating constituent unit (homopolymer), or a polymer having different repeating constituent units (copolymer), and the form of the copolymer in a case where the nitrogen-containing nonionic polymer is a copolymer may be any of a block copolymer, a random copolymer, a graft copolymer, and an alternating copolymer.

The nitrogen-containing nonionic polymer is preferably a polymer having an amide bond, more preferably a polymer having an amide bond in the side chain structure, and still more preferably at least one type selected from the group consisting of polyvinyl pyrrolidone, poly-N-vinylacetamide, polydimethylacrylamide, polyvinyl caprolactam, N-isopropylacrylamide, and an oxazoline group-containing polymer. The nitrogen-containing nonionic polymer may be used singly or in combination of two or more types thereof. As the nitrogen-containing nonionic polymer, a commercially available product may be used, or a synthetic product may be used.

The content of the nitrogen-containing nonionic polymer in the post-CMP cleaning composition is more than 0.1% by mass and less than 1.0% by mass, preferably 0.15% by mass or more and 0.8 mass % or less, more preferably 0.15% by mass or more and 0.45% by mass or less, and still more preferably 0.15% by mass or more and 0.4% by mass or less, with respect to the total mass of the post-CMP cleaning composition. If the content of the nitrogen-containing nonionic polymer is 0.1% by mass or less, with respect to the total mass of the post-CMP cleaning composition, there is a possibility that residues on the surface of the polished object to be polished may not be sufficiently removed, and if the content is 1.0% by mass or more, there is a possibility that the nitrogen-containing nonionic polymer itself remains as residues in the polished object to be polished. In addition, from the viewpoint of further reducing the value of the zeta potential on the surface of the polished object to be polished, 0.15% by mass or more and 0.20% by mass or less are particularly preferable. If two or more types of nitrogen-containing nonionic polymers are contained in the post-CMP cleaning composition, the content of the nitrogen-containing nonionic polymer means the total amount thereof.

### Anionic Polymer Containing Sulfonic Acid Group

The anionic polymer containing a sulfonic acid group contained in the post-CMP cleaning composition according to the present invention acts as a dispersant in the post-CMP cleaning composition. Containing the anionic polymer containing a sulfonic acid group in the post-CMP cleaning composition can negatively control the zeta potential of both the surface of the polished object to be polished (for example, a polished object to be polished containing silicon nitride) and a defect source such as an abrasive and organic residues to form an electrostatic repulsion layer, thereby allowing to reduce the number of defects of the polished object to be polished.

The weight-average molecular weight of the anionic polymer containing a sulfonic acid group is preferably 1,500 or more, more preferably 3,000 or more, still more preferably 4,000 or more, yet still more preferably 5,000 or more, particularly preferably 6,000 or more, particularly more preferably 7,000 or more, and most preferably 8,000 or more. In addition, the weight-average molecular weight of the anionic polymer containing a sulfonic acid group is preferably 1,000,000 or less, more preferably 500,000 or less, still more preferably 100,000 or less, yet still more preferably 50,000 or less, particularly preferably 25,000 or less, particularly more preferably 20,000 or less, and most preferably 15,000 or less. That is, the weight-average molecular weight of the anionic polymer containing a sulfonic acid group is preferably 1,500 or more and 1,000,000 or less, more preferably 3,000 or more and 500,000 or less, still more preferably 4,000 or more and 100,000 or less, yet still more preferably 5,000 or more and 50,000 or less, particularly preferably 6,000 or more and 25,000 or less, particularly more preferably 7,000 or more and 20,000 or less, and most preferably 8,000 or more and 15,000 or less. If the weight-average molecular weight of the anionic polymer containing a sulfonic acid group is within the above range, residues on the surface of the polished object to be polished can be more efficiently removed after the treatment using the post-CMP cleaning composition, and the desired effect of the present invention is further exhibited.

The anionic polymer containing a sulfonic acid group is not limited as long as it has a sulfonic acid group, and specific examples thereof include polyvinyl sulfonic acid, polystyrene sulfonic acid, polyallyl sulfonic acid, polymethallyl sulfonic acid, poly (2-acrylamide-2-methylpropane sulfonic acid), polyisoprene sulfonic acid, (meth) acrylic acid-isoprene sulfonic acid copolymer, (meth) acrylic c acid-[2-(meth) acrylamide-2-methylpropane sulfonic acid] copolymer, and (meth) acrylic acid-isoprene sulfonic acid-[2-(meth) acrylamide-2-methylpropane sulfonic acid] copolymer. These anionic polymers containing a sulfonic acid group may have the form of a neutralized salt.

In addition, as the anionic polymer containing a sulfonic acid group, not only those having the main chain structure as described above but also a graft copolymer having an anionic polymer structure containing a sulfonic acid group in a side chain can be suitably used. The anionic polymer containing a sulfonic acid group may be a polymer having the same repeating structural unit (homopolymer), or a polymer having different repeating structural units (copolymer) polymer having, and if the anionic polymer containing a sulfonic acid group is a copolymer, the form of the copolymer may be any of a block copolymer, a random copolymer, a graft copolymer, and an alternating copolymer. In addition, the repeating structure of the copolymer may be made of a repeating structure having a sulfonic acid group and a repeating structure having no sulfonic acid group, or may be made of only two or more types of repeating structures having a sulfonic acid group.

Further, the anionic group in the anionic polymer containing a sulfonic acid group may be only a sulfonic acid group, or may contain one or two or more types of anionic groups other than the sulfonic acid group.

The anionic polymer containing a sulfonic acid group may be used singly or in combination of two or more types thereof. If the post-CMP cleaning composition contains two or more types of anionic polymers containing a sulfonic acid group, the content of the anionic polymer containing a sulfonic acid group means the total amount thereof. In addition, as the anionic polymer containing a sulfonic acid group, a commercially available product may be used, or a synthetic product may be used.

The content of the anionic polymer containing a sulfonic acid group in the post-CMP cleaning composition is not particularly limited, but is preferably 0.0002% by mass or more and 2% by mass or less, more preferably 0.001% by mass or more and 0.2% by mass or less, still more preferably 0.002% by mass or more and 0.1% by mass or less, particularly preferably 0.01% by mass or more and 0.025% by mass or less, and most preferably 0.015% by mass or more and 0.02% by mass or less, with respect to the total mass of the post-CMP cleaning composition.

### Other Polymers

The post-CMP cleaning composition according to the present invention may further contain a polymer other than the nitrogen-containing nonionic polymer and the anionic polymer containing a sulfonic acid group. As the other polymer, any of a cationic polymer, an amphoteric polymer, a nitrogen-free nonionic polymer, and an anionic polymer not containing a sulfonic acid group can be used. In addition, the other polymer is preferably a water-soluble polymer. The water-soluble polymer referred to herein is a water-soluble polymer having the same repeating structural unit (homopolymer), or a water-soluble polymer having different repeating units (copolymer), and is typically a compound in which a weight-average molecular weight (Mw) is 1000 or more.

Examples of the cationic polymer include polyethyleneimine (PEI), polyvinylamine, polyallylamine, polyvinylpyridine, and a polymer of cationic acrylamide.

Examples of the amphoteric polymer include a copolymer of a vinyl monomer having an anionic group and a vinyl monomer having a cationic group, and a vinyl-based amphoteric polymer having a carboxybetaine group or a sulfobetaine group, and specifically include an acrylic acid/dimethylaminoethyl methacrylic acid copolymer and an acrylic acid/diethylaminoethyl methacrylic acid copolymer.

The nitrogen-free nonionic polymer is not limited as long as it is a nonionic polymer having no nitrogen atom, but is preferably a nonionic polymer having no nitrogen atom and having an oxygen atom. Examples of the nitrogen-free nonionic polymer include polyvinyl alcohol, polyvinyl ethers (polyvinyl methyl ether, polyvinyl ethyl ether, polyvinyl isobutyl ether, and the like), polyalkylene oxides (polyethylene oxide, polypropylene oxide, polybutylene oxide, and the like), polyglycerin, polyethylene glycol, polypropylene glycol, polybutylene glycol, water-soluble polysaccharides such as hydroxyethyl cellulose, alginic acid polyhydric alcohol esters, and dextrin derivatives.

In one embodiment, the content of a polymer other than the nitrogen-containing nonionic polymer and the anionic polymer containing a sulfonic acid group is not particularly limited, but is, for example, 0.15% by mass or less, preferably 0.10% by mass or less, more preferably less than 0.10% by mass, and still more preferably 0.05% by mass or less, with respect to the entire post-CMP cleaning composition. If two or more types of polymers other than the nitrogen-containing nonionic polymer and the anionic polymer containing a sulfonic acid group is contained in the post-CMP cleaning composition, the content thereof means the total amount thereof. In one embodiment, the post-CMP cleaning composition according to the present invention may contain no polymer other than the nitrogen-containing nonionic polymer and the anionic polymer containing a sulfonic acid group. In addition, the post-CMP cleaning composition according to the present invention may or may not contain a nitrogen-free nonionic polymer, but from the viewpoint of more exerting the effect of the nitrogen-containing nonionic polymer, it is preferable that the post-CMP cleaning composition according to the present invention does not contain a nitrogen-free nonionic polymer.

### Solvent

The post-CMP cleaning composition according to the present invention preferably contains a solvent. The solvent has a function of dispersing or dissolving each component. The solvent preferably contains water, and more preferably contains only water. In addition, the solvent may be a mixed solvent of water and an organic solvent for dispersing or dissolving each component. In this case, examples of the organic solvent to be used include acetone, acetonitrile, ethanol, methanol, isopropanol, glycerin, ethylene glycol, and propylene glycol, which are organic solvents miscible with water. In addition, these organic solvents may be used without being mixed with water, and each component may be dispersed or dissolved and then mixed with water. These organic solvents can be used singly or in combination of two or more types.

Water is preferably water that does not contain impurities as much as possible from the viewpoint of suppressing contamination of the polished object to be polished and inhibition of the action of other components. For example, water is preferably water that a total content of transition metal ions is 100 ppb by mass or less. Herein, the purity of water can be increased by, for example, operations such as removal of impurity ions using an ion exchange resin, removal of foreign matters by a filter, and distillation. Specifically, for example, deionized water (ion-exchanged water), pure water, ultrapure water, distilled water, or the like is preferably used. In the present description, the content of transition metal ions can be measured by, for example, ICP emission spectrometry.

### Chelating Agent

The post-chemical mechanical polishing cleaning composition (post-CMP cleaning composition) according to one aspect of the present invention preferably contains a chelating agent. The post-CMP cleaning composition contains a chelating agent, thereby further particularly promoting adsorption of the nitrogen-containing nonionic polymer to the surface of the polished object to be polished, and allowing to further reduce the residues. In addition, the chelating agent also has the function of adjusting the pH of the post-CMP cleaning composition. Further, forming a chelate with an impurity such as a metal ion can improve the functions of the nitrogen-containing nonionic polymer and the anionic polymer containing a sulfonic acid group. As the chelating agent, an organic compound having at least one phosphoric acid group (—OP(═O)(OH)₂) is preferable, and an organic compound having two or more phosphoric acid groups (—OP(═O)(OH)₂) is more preferable. That is, in one embodiment, the post-CMP cleaning composition of the present invention further contains a chelating agent having two or more phosphoric acid groups. Specific examples of the chelating agent include orthophosphoric acid, methyl acid phosphate, ethyl acid phosphate, ethyl glycol acid phosphate, isopropyl acid phosphate, butyl acid phosphate, 2-ethylhexyl acid phosphate, pentetic acid, phytic acid, edetic acid, 1-hydroxyethylidene-1,1-diphosphonic acid

(HEDP, also referred to as etidronic acid), polyphosphoric acid, metaphosphoric acid, hexametaphosphoric acid, phosphonobutanetricarboxylic acid, ethylenediaminetetramethylenephosphonic acid, diethylenetriaminepentamethylenephosphonic acid, aminotrimethylenephosphonic acid, and salts thereof.

If the post-CMP cleaning composition contains a chelating agent, the content of the chelating agent is not particularly limited, but is preferably 0.003% by mass or more and 0.2% by mass or less, more preferably 0.005% by mass or more and 0.1% by mass or less, and still more preferably 0.006% by mass or more and 0.06% by mass or less, with respect to the total mass of the post-CMP cleaning composition.

### Surfactant

The post-CMP cleaning composition according to the present invention may further contain a surfactant. The type of surfactant is not particularly limited, and may be any of nonionic, anionic, cationic, and amphoteric surfactants. In one embodiment, the molecular weight of the surfactant may be less than 1000.

Examples of the nonionic surfactant include compounds other than the nitrogen-containing nonionic polymer, and examples thereof include alkyl ether type such as polyoxyethylene lauryl ether and polyoxyethylene oleyl ether; alkylphenyl ether type such as polyoxyethylene octylphenyl ether; alkyl ester type such as polyoxyethylene laurate;

alkylamine type such as polyoxyethylene laurylamino ether; alkylamide type such as polyoxyethylene lauric acid amide; polypropylene glycol ether type such as polyoxyethylene polyoxypropylene ether; alkanolamide type such as oleic acid diethanolamide; and an allyl phenyl ether type such as polyoxyalkylene allyl phenyl ether. In addition, propylene glycol, diethylene glycol, monoethanolamine, alcohol ethoxylate, alkylphenol ethoxylate, tertiary acetylene glycol, alkanolamide, and the like can also be used as the nonionic surfactant. The nitrogen-containing nonionic polymer can function as a nonionic surfactant, and thus a separate nonionic surfactant may not be added.

Examples of the anionic surfactant include compounds other than the anionic polymer containing a sulfonic acid group, and examples thereof include carboxylic acid type such as sodium myristate, sodium palmitate, sodium stearate, sodium laurate, and potassium laurate; sulfuric acid ester type such as sodium octyl sulfate; phosphoric acid ester type such as lauryl phosphoric acid and sodium lauryl phosphate; and sulfonic acid type such as sodium dioctyl sulfosuccinate and sodium dodecylbenzenesulfonate. The anionic polymer containing a sulfonic acid group can function as an anionic surfactant, and thus a separate anionic surfactant may not be added.

Examples of the cationic surfactant include amines such as laurylamine hydrochloride; quaternary ammonium salts such as polyethoxyamine and lauryltrimethylammonium chloride; and pyridium salts such as lauryl pyridinium chloride.

Examples of the amphoteric surfactant include a lecithin, an alkylamine oxide, an alkyl betaine such as N-alkyl-N,N-dimethylammonium betaine, and a sulfobetaine.

The surfactant may be used singly or in combination of two or more types thereof. As the surfactant, a commercially available product may be used, or a synthetic product may be used.

If the post-CMP cleaning composition contains a surfactant, the lower limit of the content of the surfactant is preferably 0.01% by mass or more, and more preferably 0.05% by mass or more, with respect to 100% by mass of the total mass of the post-CMP cleaning composition. The upper limit of the content of the surfactant in the post-CMP cleaning composition is preferably 5% by mass or less, and more preferably 1% by mass or less, with respect to 100% by mass of the total mass of the post-CMP cleaning composition. If the post-CMP cleaning composition contains two or more types of surfactants, the content of the surfactants is intended to be the total amount thereof.

### pH of Post-Chemical Mechanical Polishing Cleaning Composition (Post-CMP Cleaning Composition)

The pH of the post-chemical mechanical polishing cleaning composition (post-CMP cleaning composition) according to the present invention is less than 7.0. The pH of the post-CMP cleaning composition is less than 7.0, whereby the electric potential on the surface of the polished object to be polished becomes positive, and the anionic polymer containing a sulfonic acid group, which is a negative charge, is likely to be adsorbed on the surface of the polished object to be polished by electrostatic attraction, and the number of defects is reduced from the viewpoint of surface protection and the viewpoint of setting the zeta potential of the surface of the polished object to be polished during cleaning to a negative value. If the pH of the post-CMP cleaning composition is 7.0 or more, the electric potential on the surface of the polished object to be polished becomes negative, and the anionic polymer containing a sulfonic acid group causes electrostatic repulsion with the surface of the polished object to be polished, and is hardly adsorbed. As a result, the surface of the polished object to be polished becomes difficult to be protected, and reattachment of residues (contaminants) to the surface of the polished object to be polished easily occurs, and as a result, the number of defects in the polished object to be polished increases. The pH of the post-CMP cleaning composition is preferably 2 or more and less than 7.0, more preferably 2 or more and 6 or less, still more preferably 2.3 or more and 5.5 or less, yet still more preferably 2.4 or more and less than 5, particularly preferably 2.4 or more and less than 4, and most preferably 2.4 or more and less than 3.

### pH Adjusting Agent

The pH of the post-CMP cleaning composition can also be adjusted by the above-described anionic polymer containing a sulfonic acid group or a chelating agent, but the post-CMP cleaning composition may further contain a pH adjusting agent.

The pH adjusting agent is not particularly limited, and a known pH adjusting agent used in the field of the post-CMP cleaning composition can be used, and for example, a known acid, base, salt thereof, or the like, other than the chelating agent described above can be used. Examples of the pH adjusting agent include organic acids such as carboxylic acids including formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, eicosapentaenoic acid, lactic acid, malic acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, amino acid, and anthranilic acid, sulfonic acid and organic phosphonic acid; inorganic acids such as nitric acid, carbonic acid, hydrochloric acid, hypophosphorous acid, phosphorous acid, phosphonic acid, boric acid, and hydrofluoric acid; hydroxides of alkali metals such as potassium hydroxide (KOH); carbonates of alkali metals such as potassium carbonate (K₂CO₃) and sodium carbonate (Na₂CO₃); hydroxide of Group 2 element; ammonia (ammonium hydroxide); and organic bases such as quaternary ammonium hydroxide compounds.

As the pH adjusting agent, a synthetic product may be used, or a commercially available product may be used. In addition, these pH adjusting agents can be used singly or in combination of two or more types thereof.

The content of the pH adjusting agent in the post-CMP cleaning composition may be appropriately selected so as to have a desired pH value of the post-CMP cleaning composition.

As the pH of the post-CMP cleaning composition, a value measured by the method described in Examples is adopted.

### Other Additives

The post-CMP cleaning composition according to one aspect of the present invention may contain other additives in an any ratio as necessary as long as the effect of the present invention is not inhibited. However, the components other than the essential components of the post-CMP cleaning composition according to one aspect of the present invention may cause foreign matters (residues), and thus it is desirable that the components are not added unless necessary, and even if the components are added, the amount thereof is preferably as small as possible. Examples of other additives include antifungal agents (antiseptic agents), dissolved gases, reductants, oxidants, and the like. The post-CMP cleaning composition according to the present invention is acidic. In addition, the post-CMP cleaning composition according to the present invention contains a polymer. Therefore, among these, the post-CMP cleaning composition according to the present invention preferably contains an antifungal agent (antiseptic agent). The antifungal agent that can be used in a case where the post-CMP cleaning composition according to the present invention contains the antifungal agent is not particularly limited, and can be appropriately selected according to the type of the polymer. Specific examples thereof include isothiazoline-based antiseptic agents such as 2-methyl-4-isothiazoline-3-one and 5-chloro-2-methyl-4-isothiazoline-3-one; methyl paraoxybenzoate (methyl parahydroxybenzoate), butyl paraoxybenzoate (butyl parahydroxybenzoate); phenylphenol (2-phenylphenol, 3-phenylphenol, 4-phenylphenol); unsaturated fatty acids such as sorbic acid; 1,2-alkanediol such as 1,2-pentanediol, 1,2-hexanediol, and 1,2-octanediol; alkyl glyceryl ether such as 2-ethylhexyl glyceryl ether (ethylhexyl glycerin); capric acid, dehydroacetic acid, and phenoxyethanol.

The antifungal agent may be used singly, or may be used in combination of two or more types thereof.

If the post-CMP cleaning composition contains an antifungal agent, the lower limit of the content (concentration) of the antifungal agent is not particularly limited, but is preferably 0.00006% by mass or more, more preferably 0.0006% by mass or more, still more preferably 0.0008% by mass or more, and particularly preferably 0.001% by mass or more, with respect to the total mass of the post-CMP cleaning composition. In addition, the upper limit of the content (concentration) of the antifungal agent is not particularly limited, but is preferably 3% by mass or less, more preferably 0.6% by mass or less, still more preferably 0.3% by mass or less, and particularly preferably 0.06% by mass or less. That is, the content (concentration) of the antifungal agent in the post-CMP cleaning composition is preferably 0.00006% by mass or more and 3% by mass or less, more preferably 0.0006% by mass or more and 0.6% by mass or less, still more preferably 0.0008% by mass or more and 0.3% by mass or less, and particularly preferably 0.001% by mass or more and 0.06% by mass or less, with respect to the total mass of the post-CMP cleaning composition. Within such a range, an effect sufficient to inactivate or destroy microorganisms is obtained. If the post-CMP cleaning composition contains two or more types of antifungal agents, the above content means the total amount thereof.

That is, in one embodiment of the present invention, the post-CMP cleaning composition is substantially made of a nitrogen-containing nonionic polymer, an anionic polymer containing a sulfonic acid group, water, and at least one selected from the group consisting of a chelating agent, an antifungal agent, an organic solvent, a pH adjusting agent, and a surfactant. In one embodiment of the present invention, it is substantially made of a nitrogen-containing nonionic polymer, an anionic polymer containing a sulfonic acid group, water, and at least one of a chelating agent, an antifungal agent, and an organic solvent. In one embodiment of the present invention, the post-CMP cleaning composition is substantially made of a nitrogen-containing nonionic polymer, an anionic polymer containing a sulfonic acid group, water, a chelating agent, and at least one of an antifungal agent, and an organic solvent. In one embodiment of the present invention, the post-CMP cleaning composition is substantially made of a nitrogen-containing nonionic polymer, an anionic polymer containing a sulfonic acid group, water, a chelating agent, an antifungal agent, and an organic solvent.

In the present embodiment, “the post-CMP cleaning composition is substantially made of X” means that the total content of X is more than 99% by mass (upper limit: 100% by mass) with respect to 100% by mass of the total mass of the post-CMP cleaning composition (with respect to the post-CMP cleaning composition). Preferably, the post-CMP cleaning composition is made of X (total content=100% by mass). For example, “the post-CMP cleaning composition is substantially made of a nitrogen-containing nonionic polymer, an anionic polymer containing a sulfonic acid group, water, and at least one of a chelating agent, an antifungal agent, and an organic solvent” means that the total content of the nitrogen-containing nonionic polymer, the anionic polymer containing a sulfonate group, water, and at least one of the chelating agent, the antifungal agent, and the organic solvent is more than 99% by mass (upper limit: 100% by mass) with respect to 100% by mass of the total mass of the post-CMP cleaning composition (with respect to the post-CMP cleaning composition), and it is preferable that the post-CMP cleaning composition is made of the nitrogen-containing nonionic polymer, the anionic polymer containing a sulfonic acid group, water, and at least one of the chelating agent, the antifungal agent, and the organic solvent (the total content=100% by mass).

For further improving the foreign matter removing effect, it is preferable that the post-chemical mechanical polishing cleaning composition (post-CMP cleaning composition) of the present invention does not substantially contain an abrasive. Herein, the “does not substantially contain an abrasive” means that the content of an abrasive with respect to the entire post-CMP cleaning composition is less than 0.1% by mass (preferably less than 0.01% by mass). That is, in the post-CMP cleaning composition of the present invention, in one embodiment, the content of an abrasive is less than 0.1% by mass with respect to 100% by mass of the total mass of the post-CMP cleaning composition.

In addition, for further improving the foreign matter removing effect, it is preferable that the post-CMP cleaning composition of the present invention does not substantially contain transition metal ions. Herein, the “does not substantially contain transition metal ions” means that the content of transition metal ions with respect to the entire post-CMP cleaning composition is less than 0.1% by mass (preferably less than 0.01% by mass). That is, in the post-CMP cleaning composition of the present invention, in one embodiment, a transition metal ion content is less than 0.1% by mass, with respect to 100% by mass of the total mass of the post-CMP cleaning composition.

### Electrical Conductivity of Post-Chemical Mechanical Polishing Cleaning Composition (Post-CMP Cleaning Composition)

The electrical conductivity (EC) of the post-CMP cleaning composition according to the present invention is not particularly limited, but is preferably 0.45 mS/cm or more, and more preferably 0.50 mS/cm or more. In addition, the upper limit of the electrical conductivity (EC) of the post-CMP cleaning composition according to the present invention is not particularly limited, but is preferably 0.65 mS/cm or less, and more preferably 0.60 mS/cm or less. That is, the electrical conductivity (EC) of the post-CMP cleaning composition according to the present invention is preferably 0.45 mS/cm or more and 0.65 mS/cm or less, and more preferably 0.50 mS/cm or more and 0.60 mS/cm or less. The electrical conductivity of the post-CMP cleaning composition can be adjusted by the type and amount of an anionic polymer containing a sulfonic acid group, a pH adjusting agent, and the like. The electrical conductivity (EC) of the post-CMP cleaning composition can be measured by the method described in Examples.

### Water Contact Angle of Polished Object to be Polished in Post-CMP Cleaning Treatment With Post-CMP Cleaning Composition

As described above, it is presumed that when the post-CMP cleaning composition according to the present invention is used, the nitrogen-containing nonionic polymer (and the anionic polymer containing a sulfonic acid group) is adsorbed on the surface of the polished object to be polished, whereby the residue present on the surface of the polished object to be polished can be desorbed. Herein, the fact that the water contact angle of the surface of the polished object to be polished is small indicates that the wettability of the surface is high, and this is considered to be due to the fact that the nitrogen atom portion of the nitrogen-containing nonionic polymer is adsorbed to the surface of the polished object to be polished to improve the hydrophilicity. Therefore, it is considered that the fact that the surface of the polished object to be polished exhibits high wettability supports that the nitrogen-containing nonionic polymer acts as in the above mechanism.

Therefore, it is preferable that the water contact angle of the polished object to be polished at the time of the post-CMP cleaning treatment be small. As an example, the water contact angle in a case where the polished object to be polished is a substrate (poly-Si substrate) having a film containing polysilicon is acceptable if 20° or less, and is preferably 15° or less.

As an example, the water contact angle in a case where the polished object to be polished is a substrate having a film containing silicon oxide (for example, a substrate having a TEOS film) is acceptable if 15° or less, and is preferably 10° or less. As an example, the water contact angle in a case where the polished object to be polished is a substrate having a film containing silicon nitride (Si₃N₄ substrate) is acceptable if 17° or less, and is preferably 13° or less. The water contact angle of the polished object to be polished can be measured by the method described in Examples.

### Zeta Potential of Polished Object to be Polished During Post-CMP Cleaning Treatment With Post-CMP Cleaning Composition

As described above, the post-CMP cleaning composition according to the present invention contains an anionic polymer containing a sulfonic acid group, and thus it is possible to control both the zeta potential of the surface of the polished object to be polished and the zeta potential of the surface of the residue (contaminant) to be negative. Therefore, it is presumed that residues (contaminants) are efficiently desorbed from the polished object to be polished using the electrostatic repulsive interaction, and further, reattachment to the polished object to be polished is suppressed.

Therefore, the zeta potential of the surface of the polished object to be polished at the time of the post-CMP cleaning treatment is preferably a negative value. As an example, in a case where the polished object to be polished is a substrate having a film containing polysilicon (poly-Si substrate), the zeta potential is acceptable if −5 mV or less, and is preferably less than −5 mV. As an example, in a case where the polished object to be polished is a substrate having a film containing silicon oxide (for example, a substrate having a TEOS film), the zeta potential is acceptable if −5 mV or less, and is preferably −10 mV or less. As an example, in a case where the polished object to be polished is a substrate having a film containing silicon nitride (Si₃N₄ substrate), the zeta potential is acceptable if −5 mV or less, and is preferably-15 mV or less. The zeta potential of the surface of the polished object to be polished at the time of the post-CMP cleaning treatment can be estimated by the method described in Examples.

### Method for Producing Post-Chemical Mechanical Polishing Cleaning Composition (Post-CMP Cleaning Composition)

The method for producing the post-CMP cleaning composition of the present invention can be obtained, for example, by stirring and mixing a nitrogen-containing nonionic polymer, an anionic polymer containing a sulfonic acid group, a solvent, and, as necessary, other components. The temperature at which each component is mixed is not particularly limited, but is preferably 10° C. or more and 40° C. or less, and heating may be performed in order to increase the rate of dissolution. In addition, the mixing time is not particularly limited.

### Post-Chemical Mechanical Polishing Cleaning Method (Post-CMP Cleaning Treatment Method; Surface Treatment Method)

Another aspect of the present invention is a post-chemical mechanical polishing cleaning method (also referred to as “post-CMP cleaning treatment method” or “surface treatment method” in the present description) including performing a post-chemical mechanical polishing cleaning treatment (also referred to as “post-CMP cleaning treatment” or “surface treatment” in the present description) on a polished object to be polished using the post-chemical mechanical polishing cleaning composition (post-CMP cleaning composition). In the present description, the post-chemical mechanical polishing cleaning method (post-CMP cleaning treatment method) refers to a method for reducing residues on the surface of the polished object to be polished, and is a method for performing cleaning in a broad sense.

According to the post-CMP cleaning treatment method according to one aspect of the present invention, residues remaining on the surface of the polished object to be polished can be sufficiently removed. That is, another aspect of the present invention provides a method for reducing residues on the surface of the polished object to be polished, in which the polished object to be polished is subjected to post-chemical mechanical polishing cleaning treatment (post-CMP cleaning treatment) using the post-chemical mechanical polishing cleaning composition (post-CMP cleaning composition). In addition, another aspect of the present invention provides a post-chemical mechanical polishing cleaning method (post-CMP cleaning method) in which the polished object to be polished containing a silicon-containing material is subjected to post-chemical mechanical polishing cleaning treatment (post-CMP cleaning treatment) using the post-chemical mechanical polishing cleaning composition (post-CMP cleaning composition) to reduce residues on the surface of the polished object to be polished.

The post-CMP cleaning treatment method according to one aspect of the present invention is performed by a method of bringing the post-CMP cleaning composition according to the present invention into direct contact with the polished object to be polished.

Examples of the post-chemical mechanical polishing cleaning method (post-CMP cleaning treatment method) mainly include (I) a method by rinse polishing treatment and (II) a method by cleaning treatment. That is, according to one aspect of the present invention, the post-chemical mechanical polishing cleaning treatment (post-CMP cleaning treatment) is preferably performed by rinse polishing treatment or cleaning treatment. That is, the post-chemical mechanical polishing cleaning method (post-CMP cleaning treatment method) is preferably a rinse polishing treatment method or a cleaning treatment method. The rinse polishing treatment and the cleaning treatment are performed in order to remove foreign matters (particles, metal contamination, organic residues, pad debris, and the like) on the surface of the polished object to be polished and obtain a clean surface. Hereinafter, the above (I) and (II) will be described.

### (I) Rinse Polishing Treatment

The post-CMP cleaning composition according to the present invention is suitably used in a rinse polishing treatment. That is, the post-CMP cleaning composition according to one aspect of the present invention can be preferably used as a rinse polishing composition. The rinse polishing treatment is performed on a polishing table (platen) to which a polishing pad is attached for the purpose of removing foreign matters on the surface of the object to be polished after performing final polishing (finish polishing) of the object to be polished. In this case, the rinse polishing treatment is performed by bringing the post-CMP cleaning composition according to the present invention into direct contact with the polished object to be polished. As a result, foreign matters on the surface of the polished object to be polished is removed by frictional force (physical action) of the polishing pad and by chemical action of the post-CMP cleaning composition. Among the foreign matters, particles and organic residues are particularly easily removed by physical action. Therefore, in the rinse polishing treatment, particles and organic residues can be effectively removed by using friction with the polishing pad on the polishing table (platen).

That is, in the present description, the rinse polishing treatment, the rinse polishing method, and the rinse polishing step respectively refer to a treatment, a method, and a step for reducing residues on the surface of the object to be subjected to post-CMP cleaning treatment using a polishing pad.

Specifically, the rinse polishing treatment can be performed by placing the surface of the polished object to be polished after the polishing step on a polishing table (platen) of a polishing apparatus, and relatively sliding the polished object to be polished and the polishing pad while bringing the polishing pad and the polished semiconductor substrate into contact with each other and supplying the post-CMP cleaning composition to the contact portion.

As the polishing apparatus, it is possible to use a general polishing apparatus including a holder for holding an object to be polished, a motor capable of changing the rotation speed, and has a polishing table to which a polishing pad (polishing cloth) can be attached.

The rinse polishing treatment can be performed using either a one-surface polishing apparatus or a both-surface polishing apparatus. In addition, the polishing apparatus preferably includes a discharge nozzle for the post-CMP cleaning composition in addition to the discharge nozzle for the polishing composition. The operating conditions of the polishing apparatus during the rinse polishing treatment are not particularly limited, and those skilled in the art can appropriately set the operating conditions.

As the polishing pad, a general nonwoven fabric, polyurethane, a porous fluororesin, and the like can be used without particular limitation. The polishing pad is preferably subjected to grooving such that the post-CMP cleaning composition is accumulated.

The rinse polishing conditions are also not particularly limited, and for example, the rotation speed of the polishing table and the rotation speed of the head (carrier) are preferably 10 rpm (0.17 s⁻¹) or more and 100 rpm (1.67 s⁻¹) or less, and the pressure (polishing pressure) applied to the polished object to be polished is preferably 0.5 psi (3.4 kPa) or more and 10 psi (68.9 kPa) or less. The method for supplying the post-CMP cleaning composition to the polishing pad is also not particularly limited, and for example, a method for continuously supplying the post-CMP cleaning composition with a pump or the like (flowing) is employed. This supply amount is not limited, but it is preferable that the surface of the polishing pad is always covered with the post-CMP cleaning composition, and it is preferable that the supply amount is 10 mL/min or more and 5000 mL/min or less. The rinse polishing time is also not particularly limited, but is preferably 5 seconds or more and 180 seconds or less.

After the rinse polishing treatment with the post-CMP cleaning composition according to one aspect of the present invention, the polished object to be polished (object to be subjected to post-chemical mechanical polishing cleaning treatment) is preferably pulled up and taken out while applying the post-CMP cleaning composition according to one aspect of the present invention.

### (II) Cleaning Treatment

The post-CMP cleaning composition according to one aspect of the present invention may be used in a cleaning treatment. That is, the post-CMP cleaning composition according to one aspect of the present invention can be preferably used as a cleaning composition. The cleaning treatment is preferably performed for the purpose of removing foreign matters on the surface of the polished object to be polished (object to be cleaned) after the final polishing (finish polishing), after the rinse polishing treatment, or after another rinse polishing treatment using a rinse polishing composition other than the post-CMP cleaning composition of the present invention, of the object to be polished. The cleaning treatment and the rinse polishing treatment are classified according to places where these treatments are performed, and the cleaning treatment is a surface treatment performed at a place other than the polishing table (platen), and is preferably a surface treatment performed after the polished object to be polished is removed from the polishing table (platen). Also in the cleaning treatment, the post-CMP cleaning composition according to the present invention is brought into direct contact with the polished object to be polished to allow to remove foreign matters on the surface of the object.

Examples of the method for performing the cleaning treatment include (i) a method for bringing a cleaning brush into contact with one surface or both surfaces of the polished object to be polished while holding the polished object to be polished, and rubbing the surface of the polished object to be polished with the cleaning brush while supplying the post-CMP cleaning composition to the contact portion, and (ii) a method for immersing the polished object to be polished in the post-CMP cleaning composition, and performing ultrasonic treatment or stirring (dip type). In such a method, the foreign matters on the surface of the polished object to be polished are removed by frictional force of the cleaning brush or by mechanical force generated by ultrasonic treatment or stirring, and by chemical action of the post-CMP cleaning composition.

In the method (i), the method for contacting the post-CMP cleaning composition with the polished object to be polished is not particularly limited, but examples thereof include a spin type in which the polished object to be polished is rotated at a high speed while flowing the post-CMP cleaning composition onto the polished object to be polished from a nozzle, and a spray type in which the post-CMP cleaning composition is sprayed onto the polished object to be polished to clean the polished object to be polished.

From the viewpoint of more efficient decontamination in a short time, it is preferable to adopt a spin type and/or a spray type for the cleaning treatment, and it is more preferable to use a spin type.

Examples of the apparatus for performing such a cleaning treatment include a batch-type cleaning apparatus that simultaneously performs post-CMP cleaning treatment on a plurality of polished objects to be polished housed in a cassette, and a single wafer type cleaning apparatus that performs post-CMP cleaning treatment with attaching one sheet of the polished object to be polished to a holder. From the viewpoint of shortening the cleaning time and the like, a method using a single wafer type cleaning apparatus is preferable.

Further, examples of the apparatus for performing the cleaning treatment include a polishing apparatus including a cleaning facility for removing a polished object to be polished from a polishing table (platen) rubbing a polished object to be polished with a cleaning brush after removing the polished object to be polished from a polishing table (platen). Using such a polishing apparatus can more efficiently achieve the cleaning treatment of the polished object to be polished.

As such a polishing apparatus, a general polishing apparatus including a holder for holding a polished object to be polished, a motor capable of changing the rotation speed, a cleaning brush, and the like can be used. As the polishing apparatus, either a one-surface polishing apparatus or a both-surface polishing apparatus may be used. If the rinse polishing step is performed after the CMP step, it is more efficient and preferable to perform the cleaning treatment using the same apparatus as the polishing apparatus used in the rinse polishing step.

The cleaning brush is not particularly limited, but is preferably a resin brush. The material of the resin brush is not particularly limited, but PVA (polyvinyl alcohol) is preferable. The cleaning brush is more preferably a PVA sponge.

The cleaning conditions are also not particularly limited, and can be appropriately set according to the type of the polished object to be polished and the type and amount of residues to be removed. For example, the rotation speed of the cleaning brush is preferably 10 rpm (0.17 s⁻¹) or more and 200 rpm (3.33 s⁻¹) or less, and the rotation speed of the polished object to be polished is preferably 10 rpm (0.17 s⁻¹) or more and 100 rpm (1.67 s⁻¹) or less. The pressure (polishing pressure) applied to the polished object to be polished is preferably 0.5 psi (3.4 kPa) or more and 10 psi (68.9 kPa) or less. The method for supplying the post-CMP cleaning composition to the cleaning blush is also not particularly limited, and for example, a method for continuously supplying the post-CMP cleaning composition with a pump or the like (flowing) is employed. This supply amount is not limited, but it is preferable that the surfaces of the cleaning blush and the polished object to be polished are always covered with the post-CMP cleaning composition, and it is preferable that the supply amount is 10 mL/min or more and 5000 mL/min or less. The cleaning time is also not particularly limited, but the step of using the post-CMP cleaning composition according to one aspect of the present invention has preferably 5 seconds or more and 180 seconds or less. Within such a range, the foreign matters can be more effectively removed.

The temperature of the post-CMP cleaning composition at the time of cleaning is not particularly limited, and may be typically room temperature, but may be heated to about 40° C. or more and 70° C. or less as long as the performance is not impaired.

In the method (ii), the condition of the cleaning method by immersion is not particularly limited, and a known method can be used.

Cleaning with water may be performed before performing the post-CMP cleaning treatment by the method (I) or (II).

### Post-Cleaning Treatment

In addition, as the post-CMP cleaning treatment method, it is preferable to perform a further cleaning treatment of the polished object to be polished after the post-CMP cleaning treatment (I) or (II) using the post-CMP cleaning composition according to one aspect of the present invention. In the present description, this cleaning treatment is referred to as post-cleaning treatment. The post-cleaning treatment is not particularly limited, and examples thereof include a method for simply flowing water through the polished object to be polished, and a method for simply immersing the polished object to be polished in water. In addition, similarly to the post-CMP cleaning treatment by the method (II) described above, there are a method in which the surface of the polished object to be polished is rubbed with the cleaning brush (brush cleaning) while bringing the cleaning brush into contact with one surface or both surfaces of the polished object to be polished with holding the polished object to be polished and while supplying water or an aqueous solution (for example, NH₃ aqueous solution) to the contact portion or supplying water and an aqueous solution (for example, NH₃ aqueous solution) in any order (supplying water and then supplying the aqueous solution or supplying the aqueous solution and then supplying water), a method in which the polished object to be polished is immersed in water and subjected to ultrasonic treatment or stirring (dip type), and the like. Among these methods, it is preferable to employ a method in which the surface of the polished object to be polished is rubbed with the cleaning brush while bringing the cleaning brush into contact with one surface or both surfaces of the polished object to be polished with holding the polished object to be polished and while supplying water or an aqueous solution (for example, NH₃ aqueous solution) or water and an aqueous solution (for example, NH₃ aqueous solution) to the contact portion in any order (supplying water and then supplying the aqueous solution or supplying the aqueous solution and then supplying water). As the apparatus and conditions of the post-cleaning treatment, the description of the treatment (II) described above can be referred to. Herein, it is particularly preferable to use deionized water as water used for the post-cleaning treatment.

Performing the post-CMP cleaning treatment with the post-CMP cleaning composition according to one aspect of the present invention causes the residue to be easily removed. Therefore, performing the post-CMP cleaning treatment with the post-CMP cleaning composition according to one aspect of the present invention, and then performing a further cleaning treatment using water removes the residue favorably.

In addition, it is preferable that the polished object to be polished after the post-CMP cleaning treatment or after the post-cleaning is dried by wiping off water droplets attached to the surface with a spin dryer or the like. In addition, the surface of the polished object to be polished may be dried by air blow drying.

### Method for Producing Semiconductor Substrate

The post-CMP cleaning treatment method according to one aspect of the present invention is preferably applied if the polished object to be polished is a polished semiconductor substrate. That is, according to another aspect of the present invention, there is also provided a method for producing a semiconductor substrate, in which the polished object to be polished is a polished semiconductor substrate, and the method includes subjecting the polished semiconductor substrate to the post-CMP cleaning treatment method to reduce residues on the surface of the polished semiconductor substrate. Therefore, according to the present invention, there is provided a method for producing a semiconductor substrate in which the polished object to be polished is a polished semiconductor substrate, the method including: a polishing step of polishing a pre-polishing semiconductor substrate containing a silicon-containing material, for example, at least one type selected from the group consisting of silicon oxide, polysilicon, and silicon nitride, using a polishing composition containing an abrasive, to provide a polished semiconductor substrate; and a post-chemical mechanical polishing cleaning step (also referred to as “post-CMP cleaning step” or “surface treatment step” in the present description) of reducing residues containing an abrasive on a surface of the polished semiconductor substrate, using the post-chemical mechanical polishing cleaning composition (post-CMP cleaning composition).

The details of the semiconductor substrate to which such a production method is applied are as described for the polished object to be polished subjected to the post-CMP cleaning treatment with the post-CMP cleaning composition.

In addition, the method for producing a semiconductor substrate is not particularly limited as long as the method includes a post-CMP cleaning treatment step using the post-CMP cleaning composition according to one aspect of the present invention on the surface of the polished semiconductor substrate. Examples of such a production method include a method including a polishing step and a cleaning step for forming a polished semiconductor substrate.

In addition, another example is a method including a rinse polishing step between the polishing step and the cleaning step in addition to the polishing step and the cleaning step. Each of these steps will be described below.

### Polishing Step

The polishing step that can be included in the method for producing a semiconductor substrate is a step of polishing the semiconductor substrate to form a polished semiconductor substrate.

The polishing step is not particularly limited as long as it is a step of polishing a semiconductor substrate, but it is a step of chemical mechanical polishing (CMP) step. In addition, the polishing step may be a polishing step including a single step or a polishing step including a plurality of steps. Examples of the polishing step including a plurality of steps include a step of performing a finish polishing step after the preliminary polishing step (rough polishing step), and a step of performing one or two or more secondary polishing steps after the primary polishing step and then performing the finish polishing step. The post-CMP cleaning treatment step using the post-CMP cleaning composition according to one aspect of the present invention is preferably performed after the finish polishing step.

As the polishing composition, a known polishing composition can be appropriately used according to the characteristics of the semiconductor substrate. The polishing composition is not particularly limited, but for example, a composition containing an abrasive, a solvent, a water-soluble polymer, a pH adjusting agent, and the like can be preferably used. Specific examples of such a polishing composition include a polishing composition containing silicon oxide (for example, colloidal silica), polyvinyl pyrrolidone, ammonia, and water.

The abrasive may be any of an inorganic particle, an organic particle, and an organic-inorganic composite particle. Specific examples of the inorganic particle include a particle made of a metal oxide such as silicon oxide, alumina, ceria, and titania, a silicon nitride particle, a silicon carbide particle, and a boron nitride particle. Specific examples of the organic particle include a polymethyl methacrylate (PMMA) particle. As the abrasive, a commercially available product or a synthetic product may be used. Further, the abrasive may be surface-modified. The abrasive may be used singly or in combination of two or more types thereof.

The lower limit of the average primary particle size of the abrasive is preferably 10 nm or more, more preferably 15 nm or more, still more preferably 20 nm or more, and yet still more preferably 30 nm or more. Within such a range, a high polishing removal rate can be maintained, resulting in a suitable use in the rough polishing step. The upper limit of the average primary particle size of the abrasive is preferably 200 nm or less, more preferably 150 nm or less, and still more preferably 100 nm or less. In some aspects, the average primary particle size may be 75 nm or less, 60 nm or less, or 50 nm or less. Within such a range, the occurrence of defects on the surface of the object to be polished after polishing can be further suppressed. The average primary particle size of the abrasive is calculated, for example, based on the specific surface area of the abrasive measured by the BET method.

The lower limit of the average secondary particle size of the abrasive is preferably 15 nm or more, more preferably 30 nm or more, still more preferably 40 nm or more, yet still more preferably 50 nm or more, and particularly preferably 60 nm or more. Within such a range, a high polishing removal rate can be maintained. In addition, the upper limit of the average secondary particle size of the abrasive is preferably 300 nm or less, more preferably 200 nm or less, still more preferably 150 nm or less, yet still more preferably 100 nm or less, and particularly preferably 80 nm or less. Within such a range, the occurrence of defects on the surface of the object to be polished after polishing can be further suppressed. The average secondary particle size of the abrasive can be measured by a dynamic light scattering method. For example, the weight average molecular weight can be measured using model “FPAR-1000” manufactured by Otsuka Electronics Co., Ltd. or its equivalent product.

If the polishing composition is used as a polishing liquid as it is, the content of the abrasive is preferably 0.1% by mass or more, more preferably 0.4% by mass or more, and still more preferably 1.0% by mass or more, with respect to the polishing composition. The polishing removal rate is improved by increasing the content of the abrasive. In addition, if the polishing composition is used as a polishing liquid as it is, the content of the abrasive is typically appropriately 10% by mass or less, preferably 5% by mass or less, more preferably 3% by mass or less, and still more preferably 2% by mass or less, from the viewpoint of scratch prevention and the like. It is also preferable from the viewpoint of economic efficiency to reduce the content of the abrasive. If two or more types of abrasives are used in combination, the above content refers to the total content of two or more types of abrasives.

The pH adjusting agent and the solvent are the same as defined in the sections (pH adjusting agent) and (Solvent), respectively, and thus the description thereof is omitted herein.

As the polishing apparatus, it is possible to use a general polishing apparatus including a holder for holding an object to be polished, a motor, and the like capable of changing the rotation speed, and a polishing table to which a polishing pad (polishing cloth) can be attached.

As the polishing apparatus, either a one-surface polishing apparatus or a both-surface polishing apparatus may be used.

As the polishing pad, a general nonwoven fabric, polyurethane, a porous fluororesin, and the like can be used without particular limitation. The polishing pad is preferably subjected to grooving such that the polishing liquid is accumulated.

The polishing conditions are also not particularly limited, and for example, the rotation speed of the polishing table and the rotation speed of the head (carrier) are preferably 10 rpm (0.17 s⁻¹) or more and 100 rpm (1.67 s⁻¹) or less, and the pressure (polishing pressure) applied to the object to be polished is preferably 0.5 psi (3.4 kPa) or more and 10 psi (68.9 kPa) or less. The method for supplying the polishing composition to the polishing pad is also not particularly limited, and for example, a method for continuously supplying the post-CMP cleaning composition with a pump or the like (flowing) is employed. This supply amount is not limited, but it is preferable that the surface of the polishing pad is always covered with the polishing composition, and it is preferable that the supply amount is 10 mL/min or more and 5000 mL/min or less. The polishing time is also not particularly limited, but the step of using the polishing composition has preferably 5 seconds or more and 180 seconds or less.

### Post-Chemical Mechanical Polishing Cleaning Treatment Step (Post-CMP Cleaning Treatment Step)

The post-CMP cleaning treatment step refers to a step of reducing residues on the surface of the polished object to be polished using the post-CMP cleaning composition according to the present invention. In the method for producing a semiconductor substrate, after the rinse polishing step, a cleaning step as a post-CMP cleaning treatment step may be performed, or only the rinse polishing step or only the cleaning step may be performed.

### Rinse Polishing Step

The rinse polishing step may be provided between the polishing step and the cleaning step in the method for producing a semiconductor substrate. The rinse polishing step is a step of reducing foreign matters on the surface of the polished object to be polished (polished semiconductor substrate) by the post-CMP cleaning treatment method (rinse polishing treatment method) according to one aspect of the present invention.

Details of the rinse polishing method used in the rinse polishing step are as described in the explanation of the rinse polishing treatment.

### Cleaning Step

The cleaning step may be provided after the polishing step or may be provided after the rinse polishing step in the method for producing a semiconductor substrate. The cleaning step is a step of reducing foreign matters on the surface of the polished object to be polished (polished semiconductor substrate) by the post-CMP cleaning treatment method (cleaning method) according to one aspect of the present invention.

Details of the cleaning method used in the cleaning step are as described in the explanation of the cleaning method.

The embodiments of the present invention have been described in detail, but this is illustrative and exemplary and not restrictive, and it is clear that the scope of the present invention should be interpreted by the appended claims.

The present invention includes the following aspects and embodiments.

1. A post-chemical mechanical polishing cleaning composition containing a nitrogen-containing nonionic polymer and an anionic polymer containing a sulfonic acid group, wherein a content of the nitrogen-containing nonionic polymer is more than 0.1% by mass and less than 1.0% by mass with respect to the entire post-chemical mechanical polishing cleaning composition, and a pH is less than 7.0:

2. The post-chemical mechanical polishing cleaning composition according to 1., wherein the nitrogen-containing nonionic polymer has an amide bond:

3. The post-chemical mechanical polishing cleaning composition according to 1. or 2., wherein a weight-average molecular weight of the nitrogen-containing nonionic polymer is 80,000 or less:

4. The post-chemical mechanical polishing cleaning composition according to any one of 1. to 3., wherein the nitrogen-containing nonionic polymer comprises at least one selected from the group consisting of polyvinyl pyrrolidone, poly-N-vinylacetamide, polydimethylacrylamide, polyvinyl caprolactam, N-isopropylacrylamide, and an oxazoline group-containing polymer:

5. The post-chemical mechanical polishing cleaning composition according to any one of 1. to 4., further containing a chelating agent having 2 or more phosphoric acid groups:

6. The post-chemical mechanical polishing cleaning composition according to any one of 1. to 5., which is substantially free of an abrasive:

7. A post-chemical mechanical polishing cleaning method for surface-treating a polished object to be polished containing at least one type selected from the group consisting of silicon oxide, polysilicon, and silicon nitride using the post-chemical mechanical polishing cleaning composition according to any one of 1. to 6., to reduce residues on a surface of the polished object to be polished:

8. The post-chemical mechanical polishing cleaning method according to 7., which is a rinse polishing treatment method or a cleaning treatment method:

9. A method for producing a semiconductor substrate, a polished object to be polished being a polished semiconductor substrate, the method including: a polishing step of polishing a pre-polishing semiconductor substrate containing at least one selected from the group consisting of silicon oxide, polysilicon, and silicon nitride using a polishing composition containing an abrasive to provide a polished semiconductor substrate; and a post-chemical mechanical polishing cleaning step of reducing residues containing the abrasive on a surface of the polished semiconductor substrate using the post-chemical mechanical polishing cleaning composition according to any one of 1. to 6.

### EXAMPLES

The present invention will be described in more detail with reference to the following Examples and Comparative Examples. However, the technical scope of the present invention is not limited only to the following Examples. Unless otherwise specified, “%” and “part” mean “% by mass” and “part by mass”, respectively. In addition, in the following Examples, unless otherwise specified, the operation was performed under the conditions of a room temperature (25° C.) and a relative humidity of 40% RH or more and 50% RH or less.

### Preparation of Polymer

The following nitrogen-containing nonionic polymer and anionic polymer containing a sulfonic acid group were prepared.

### Nitrogen-Containing Nonionic Polymer

Polyvinylpyrrolidone (DKS Co. Ltd., product name: PITZCOL (registered trademark) K30A): weight-average molecular weight 45,000

### Anionic Polymer Containing Sulfonic Acid Group

Sodium salt of copolymer of acrylic acid and 2-acrylamide-2-methylpropane sulfonic acid (hereinafter, “acrylic acid-sulfonic acid copolymer”) (product name: ARON A-6012 (TOAGOSEI CO., LTD.)): weight-average molecular weight 12,000

The weight-average molecular weight of the polymer was measured by the following method.

### Measurement of Weight-Average Molecular Weight (Mw) of Polymer

As the weight-average molecular weight (Mw) of the polymer, a value of the weight-average molecular weight (in terms of polyethylene glycol) measured by gel permeation chromatography (GPC) was used. The weight-average molecular weight was measured by the following apparatus and conditions:

GPC apparatus, manufactured by SHIMADZU CORPORATION

Model: Prominence+ELSD detector (ELSD-LTII)

Column: VP-ODS (manufactured by SHIMADZU CORPORATION)

Mobile phase A: MeOH

Mobile phase B: 1% acetic acid aqueous solution

Flow rate: 1 mL/min

Detector: ELSD temp. 40° C., Gain 8, N₂GAS 350 kPa

Oven temperature: 40° C.

Injection volume: 40 μL.

### Measurement of pH of Post-CMP Cleaning Composition

The pH of the post-CMP cleaning composition (liquid temperature: 25° C.) was confirmed by a pH meter (manufactured by HORIBA, Ltd., product name: LAQUA (registered trademark)).

### Electrical Conductivity of Post-CMP Cleaning Composition

The electrical conductivity (EC) of the post-CMP cleaning composition was measured with a tabletop electrical conductivity meter (manufactured by HORIBA, Ltd., model number: DS-71 LAQUA (registered trademark)).

### Preparation of Post-CMP Cleaning Composition

### Example 1

A polyvinylpyrrolidone having a weight-average molecular weight of 45,000 as the nitrogen-containing nonionic polymer; an acrylic acid-sulfonic acid copolymer having a weight-average molecular weight of 12,000 as an anionic polymer containing a sulfonic acid group; water (deionized water) as a solvent; and 1-hydroxyethane-1,1-diphosphonic acid (hereinafter, “HEDP”) (product name: Dequest (registered trademark) 2010EL (Italmatch Japan Ltd.)) as a chelating agent; ammonia (product name: EL ammonium aqueous solution KANTO CHEMICAL CO., INC.)) as a pH adjusting agent; and an antifungal agent (antiseptic agent) (San-Ai-Bac R-30 (manufactured by SAN-AI OBBLI CO., LTD.)) were stirred and mixed at 25° C. for 5 minutes to prepare a post-CMP cleaning composition A1.

Herein, the content of the nitrogen-containing nonionic polymer in the post-CMP cleaning composition was 0.15% by mass with respect to the total mass of the post-CMP cleaning composition A1; the content of the anionic polymer containing a sulfonic acid group was 0.02% by mass with respect to the total mass of the post-CMP cleaning composition A1; the content of the chelating agent was 0.024% by mass with respect to the total mass of the post-CMP cleaning composition A1; the content of the pH adjusting agent was such an amount that the pH of the post-CMP cleaning composition Al becomes 2.8; and the content of the antifungal agent was 0.0012% by mass with respect to the total mass of the post-CMP cleaning composition A1.

### Examples 2 to 11, Comparative Examples 1 to 5

Post-CMP cleaning compositions A2 to A11 and post-CMP cleaning compositions B1 to B5 were prepared in the same manner as in Example 1 except that the contents of the nitrogen-containing nonionic polymer, the anionic polymer containing a sulfonic acid group, and the chelating agent were changed as shown in Table 1 below.

In Table 1, the nitrogen-containing nonionic polymer was described as “N-containing nonionic polymer”, and the acrylic acid-sulfonic acid copolymer was described as “AA-SA copolymer”.

In addition, in Table 1, “PVP” represents polyvinylpyrrolidone, and “PVA” represents polyvinyl alcohol. In addition, in Table 1, the description of “-” (hyphen) represents that the compound is not added.

TABLE 1

| | N-containing nonionic | | | Anionic polymer containing | | | | |
|---|---|---|---|---|---|---|---|---|
| | polymer | | | sulfonic acid group | | | | |
| | | | Content | | | Content | Other | |
| | | Molecular | [% by | | Molecular | [% by | polymers | |
| | Compound | weight | mass] | Compound | weight | mass] | Compound | |
| Example 1 | PVP | 45000 | 0.15 | AA/SA | 12000 | 0.02 | — | |
| | | | | Copolymer | | | | |
| Example 2 | PVP | 45000 | 0.25 | AA/SA | 12000 | 0.02 | — | |
| | | | | Copolymer | | | | |
| Example 3 | PVP | 45000 | 0.30 | AA/SA | 12000 | 0.02 | — | |
| | | | | Copolymer | | | | |
| Example 4 | PVP | 45000 | 0.45 | AA/SA | 12000 | 0.02 | — | |
| | | | | Copolymer | | | | |
| Example 5 | PVP | 45000 | 0.60 | AA/SA | 12000 | 0.02 | — | |
| | | | | Copolymer | | | | |
| Example 6 | PVP | 45000 | 0.25 | AA/SA | 12000 | 0.02 | — | |
| | | | | Copolymer | | | | |
| Example 7 | PVP | 45000 | 0.15 | AA/SA | 12000 | 0.01 | — | |
| | | | | Copolymer | | | | |
| Example 8 | PVP | 45000 | 0.15 | AA/SA | 12000 | 0.02 | — | |
| | | | | Copolymer | | | | |
| Example 9 | PVP | 45000 | 0.15 | AA/SA | 12000 | 0.03 | — | |
| | | | | Copolymer | | | | |
| Example 10 | PVP | 45000 | 0.15 | AA/SA | 12000 | 0.02 | — | |
| | | | | Copolymer | | | | |
| Example 11 | PVP | 45000 | 0.15 | AA/SA | 12000 | 0.02 | PVA | |
| | | | | Copolymer | | | | |
| Comparative | PVP | 45000 | 0.01 | AA/SA | 12000 | 0.02 | — | |
| Example 1 | | | | Copolymer | | | | |
| Comparative | PVP | 45000 | 0.05 | AA/SA | 12000 | 0.02 | — | |
| Example 2 | | | | Copolymer | | | | |
| Comparative | PVP | 45000 | 0.10 | AA/SA | 12000 | 0.02 | — | |
| Example 3 | | | | Copolymer | | | | |
| Comparative | PVP | 45000 | 0.10 | AA/SA | 12000 | 0.01 | PVA | |
| Example 4 | | | | Copolymer | | | | |
| Comparative | PVP | 45000 | 1.00 | AA/SA | 12000 | 0.02 | — | |
| Example 5 | | | | Copolymer | | | | |
| | | | | | Antifungal agent | | | |
| | Other polymers | | Chelating agent | | (antiseptic agent) | | | |
| | | Content | | Content | | Content | pH | |
| | Molecular | [% by | | [% by | | [% by | adjusting | |
| | weight | mass] | Compound | mass] | Compound | mass] | agent | pH |
| Example 1 | — | — | HEDP | 0.024 | Isothiazoline- | 0.0012 | Ammonia | 2.8 |
| | | | | | based | | | |
| | | | | | compound | | | |
| Example 2 | — | — | HEDP | 0.024 | Isothiazoline- | 0.0012 | Ammonia | 2.8 |
| | | | | | based | | | |
| | | | | | compound | | | |
| Example 3 | — | — | HEDP | 0.024 | Isothiazoline- | 0.0012 | Ammonia | 2.8 |
| | | | | | based | | | |
| | | | | | compound | | | |
| Example 4 | — | — | HEDP | 0.024 | Isothiazoline- | 0.0012 | Ammonia | 2.8 |
| | | | | | based | | | |
| | | | | | compound | | | |
| Example 5 | — | — | HEDP | 0.024 | Isothiazoline- | 0.0012 | Ammonia | 2.8 |
| | | | | | based | | | |
| | | | | | compound | | | |
| Example 6 | — | — | HEDP | 0.012 | Isothiazoline- | 0.0012 | Ammonia | 2.8 |
| | | | | | based | | | |
| | | | | | compound | | | |
| Example 7 | — | — | HEDP | 0.012 | Isothiazoline- | 0.0012 | Ammonia | 2.8 |
| | | | | | based | | | |
| | | | | | compound | | | |
| Example 8 | — | — | HEDP | 0.012 | Isothiazoline- | 0.0012 | Ammonia | 2.8 |
| | | | | | based | | | |
| | | | | | compound | | | |
| Example 9 | — | — | HEDP | 0.012 | Isothiazoline- | 0.0012 | Ammonia | 2.8 |
| | | | | | based | | | |
| | | | | | compound | | | |
| Example 10 | — | — | — | — | Isothiazoline- | 0.0012 | Ammonia | 2.8 |
| | | | | | based | | | |
| | | | | | compound | | | |
| Example 11 | 10000 | 0.10 | HEDP | 0.012 | Isothiazoline- | 0.0012 | Ammonia | 2.8 |
| | | | | | based | | | |
| | | | | | compound | | | |
| Comparative | — | — | HEDP | 0.024 | Isothiazoline- | 0.0012 | Ammonia | 2.8 |
| Example 1 | | | | | based | | | |
| | | | | | compound | | | |
| Comparative | — | — | HEDP | 0.012 | Isothiazoline- | 0.0012 | Ammonia | 2.8 |
| Example 2 | | | | | based | | | |
| | | | | | compound | | | |
| Comparative | — | — | HEDP | 0.012 | Isothiazoline- | 0.0012 | Ammonia | 2.8 |
| Example 3 | | | | | based | | | |
| | | | | | compound | | | |
| Comparative | 10000 | 0.10 | HEDP | 0.012 | Isothiazoline- | 0.0012 | Ammonia | 2.8 |
| Example 4 | | | | | based | | | |
| | | | | | compound | | | |
| Comparative | — | — | HEDP | 0.024 | Isothiazoline- | 0.0012 | Ammonia | 2.8 |
| Example 5 | | | | | based | | | |
| | | | | | compound | | | |

### Preparation of Polished Object to be Polished

A polished object to be polished after being polished by the following chemical mechanical polishing (CMP) step was prepared.

### CMP Step

As an object to be polished, there were prepared (1) a silicon wafer having a polycrystalline silicon film (in the present description, also referred to as a poly-Si substrate or a polysilicon substrate) with a thickness of 5000 Å formed on a surface thereof (300 mm, blanket wafer, manufactured by D&X CO., LTD.), (2) a silicon wafer having a TEOS film (also referred to as a TEOS substrate) with a thickness of 10,000 Å formed on a surface thereof (300 mm, blanket wafer, manufactured by ADVANTECH CO., LTD.), and (3) a silicon wafer having a silicon nitride (Si₃N₄) film (also referred to as a Si₃N₄ substrate) with a thickness of 2500 Å formed on a surface thereof (300 mm, blanket wafer, manufactured by ADVANTECH CO., LTD.) were prepared. Note that 1 Å=0.1 nm.

For the poly-Si substrate, TEOS substrate, and Si₃N₄ substrate prepared above, a polishing composition (composition: 5-fold diluted slurry containing 10% by mass of colloidal silica (average primary particle size: 35 nm, average secondary particle size: 70 nm), 0.25% by mass of polyvinylpyrrolidone (manufactured by DKS Co. Ltd., PITSCOL (registered trademark) K-30A), and 0.33% by mass of ammonia (ammonium hydroxide)) was used to perform polishing under the following conditions. Note that 1 rpm=0.017 s^{-1.}

### Polishing Apparatus and Polishing Conditions

Polishing apparatus: FREX300E manufactured by EBARA CORPORATION

Polishing pad: foamed polyurethane pad H800 manufactured by FUJIBO HOLDINGS, INC.

Conditioner (dresser): nylon brush (manufactured by 3M Company)

Polishing pressure: 2.0 psi (1 psi=6894.76 Pa. The same applies below.)

Rotation speed of polishing table: 80 rpm

Head rotation speed: 80 rpm

Supply of polishing composition: flowing

Amount of polishing composition supplied: 200 mL/min

Polishing time: 30 seconds

### Post-Chemical Mechanical Polishing Cleaning Treatment (Post-CMP Cleaning Treatment)

### Rinse Polishing

After the surface of the object to be polished was polished in the CMP step, the polished object to be polished was removed from the polishing table (platen). Subsequently, the polished object to be polished was mounted on another polishing table (platen) in the same polishing apparatus, and a rinse polishing treatment was performed on the surface of the polished object to be polished using the post-CMP cleaning compositions A1 to A11 and B1 to B5 prepared in Examples 1 to 11 and Comparative Examples 1 to 5 under the following conditions.

### Rinse Polishing Apparatus and Rinse Polishing Conditions

Polishing pressure: 1.0 psi

Rotation speed of table: 80 rpm

Head rotation speed: 80 rpm

Supply of post-CMP cleaning composition: flowing

Amount of post-CMP cleaning composition supplied: 300 mL/min

Polishing time: 60 seconds

### Post-Cleaning

After the rinse polishing treatment, the surface of the substrate was brushed for 20 seconds using 0.3% by mass of a NH₃ aqueous solution, and then cleaning with deionized water was performed for 40 seconds to provide a polished object to be polished after rinse polishing.

### Evaluation 1: Measurement of Number of Residues

The number of residues on the surface was evaluated in each of the TEOS substrate, the poly-Si substrate, and the Si₃N₄ substrate obtained by subjecting the polished object to be polished obtained in the above section [Preparation of polished object to be polished] to the cleaning treatment by the method described in the above section [Post-chemical mechanical polishing cleaning treatment (post-CMP cleaning treatment)]. Specifically, using an optical inspection machine Surfscan (registered trademark) SP5 manufactured by KLA Corporation, the number of residues at a diameter of 40 nm for the TEOS substrate and the Si₃N₄ substrate and at a diameter of more than 70 nm for the poly-Si substrate was counted for the remaining portion excluding a portion having a width of 5 mm from the outer peripheral end (a portion from a width of 0 mm to a width of 5 mm in a case where the outer peripheral end portion is 0 mm) of one surface of the polished TEOS substrate, poly-Si substrate, and Si₃N₄ substrate. Thereafter, regarding the polished TEOS substrate, poly-Si substrate, and Si₃N₄ substrate, the number of abrasive residues and the number of organic residues were measured by SEM observation using Review SEM RS6000 manufactured by Hitachi High-Technologies Corporation. First, by SEM observation, 100 residues existing in the remaining portion excluding the portion having a width of 5 mm from the outer peripheral end portion of one surface of the polished TEOS substrate, the poly-Si substrate, and the Si₃N₄ substrate were sampled. Then, the type of residue (an abrasive residue or an organic residue) was determined by visual SEM observation from among the sampled 100 residues, and the number of residues was confirmed for each of the abrasive residues (SiO₂ residues) and the organic residues (pad scraps, polymers, and the like). The results are shown in Table 2 below.

The number of abrasive residues (SiO₂ residues) is preferably as small as possible. As an example, the number of abrasive residues having a diameter of 70 nm or more on the poly-Si substrate is acceptable if 25 or less, and is preferably 20 or less, more preferably 15 or less, still more preferably 10 or less, and particularly preferably 9 or less. As an example, the number of abrasive residues having a diameter of 40 nm or more on the TEOS substrate is acceptable if 300 or less, and is preferably 250 or less. As an example, the number of abrasive residues having a diameter of 40 nm or more on the Si₃N₄ substrate is acceptable if 300 or less, and is preferably 250 or less.

In addition, the number of organic residues (pad scraps, polymers, and the like) is preferably as small as possible. As an example, the number of organic residues (pad scraps, polymers, and the like) having a diameter of 70 nm or more on the poly-Si substrate is acceptable if 150 or less, and is preferably 100 or less, and is more preferably 90 or less. As an example, the number of organic residues (pad scraps, polymers, and the like) having a diameter of 40 nm or more on the TEOS substrate is acceptable if 200 or less, and is preferably 150 or less, and more preferably 130 or less. As an example, the number of organic residues (pad scraps, polymers, and the like) having a diameter of 40 nm or more on the Si₃N₄ substrate is acceptable if 50 or less, and is preferably 30 or less.

### Evaluation 2: Measurement of Water Contact Angle (Wettability)

The water contact angle was measured for the poly-Si substrate, the TEOS substrate, and the Si₃N₄ substrate after the rinse polishing treatment using the post-CMP cleaning compositions A1 to A11 and B1 to B4 prepared in Examples 1 to 11 and Comparative Examples 1 to 5.

Each substrate (poly-Si substrate, TEOS substrate, and Si₃N₄ substrate) used in the above section [Preparation of polished object to be polished] was cut into 60 mm square to prepare a test substrate. Subsequently, polishing was performed in the same manner as in the above [Preparation of polished object to be polished] to provide a polished object to be polished. Thereafter, the polished object to be polished was mounted on a polishing table (platen) in the following polishing apparatus, and a rinse polishing treatment was performed using the post-CMP cleaning compositions A1 to A11 and B1 to B5 prepared in Examples 1 to 11 and Comparative Examples 1 to 5 under the following conditions.

### Rinse Polishing Apparatus and Rinse Polishing Conditions (for Wettability Evaluation)

Polishing apparatus: wrapping machine EJ-380 IN-C manufactured by Engis Japan Corporation

Polishing pad: foamed polyurethane pad H800 manufactured by FUJIBO HOLDINGS, INC.

Conditioner (dresser): nylon brush (manufactured by 3M Company)

Polishing pressure: 1.0 psi

Rotation speed of polishing table: 60 rpm

Head rotation speed: 60 rpm

Supply of post-CMP cleaning composition: flowing

Amount of post-CMP cleaning composition supplied: 100 mL/min

Polishing time: 60 seconds

After the rinse polishing treatment was performed as described above, moisture on the surface was removed by air shower without performing the post-cleaning treatment to provide a polished object to be polished after rinse polishing. Thereafter, the water contact angle was measured using the θ/2 method. For the measurement, a contact angle evaluation apparatus DMo-501 manufactured by Kyowa Interface Science Co., Ltd was used. The results are shown in Table 2 below.

### Evaluation 3: Measurement of Zeta Potential

A test substrate of the poly-Si substrate, TEOS substrate, and Si₃N₄ substrate used in the above [Evaluation 2: measurement of water contact angle (wettability)] was prepared as an object to be measured. The object to be measured was placed in a solid zeta potential measuring instrument SurPASS3 (zeta potential meter) manufactured by Anton Paar Japan K.K. Subsequently, each of the post-CMP cleaning compositions A1 to A11 and B1 to B5 prepared in Examples 1 to 11 and Comparative Examples 1 to 5 was passed through an object to be measured, and the zeta potential (mV) of these objects to be measured was measured. This value was taken as the zeta potential of each wafer during rinse polishing. The results are shown in Table 2 below.

TABLE 2

| | | | | | | | | Number of residues (pieces) | | | | | |
|---|---|---|---|---|---|---|---|---|---|---|---|---|---|
| | | | | | | | | | | TEOS (SiO₂) | | Si₃N₄ | |
| | Electrical | Contact angle (°) | | | Zeta potential (mV) | | | Poly-Si (>70 nm) | | (>40 nm) | | (>40 nm) | |
| | conductivity | Poly- | TEOS | | Poly- | TEOS | | Abrasive | Organic | Abrasive | Organic | Abrasive | Organic |
| | (mS/cm) | Si | (SiO₂) | Si₃N₄ | Si | (SiO₂) | Si₃N₄ | residue | residue | residue | residue | residue | residue |
| Example 1 | 0.64 | 11 | 8 | 11 | −8 | −15 | −17 | 4 | 26 | 249 | 125 | 245 | 29 |
| Example 2 | 0.58 | 9 | 8 | 12 | −8 | −12 | −14 | 3 | 13 | 189 | 102 | 161 | 16 |
| Example 3 | 0.54 | 8 | 8 | 11 | −8 | −10 | −15 | 1 | 26 | 100 | 88 | 106 | 3 |
| Example 4 | 0.50 | 8 | 8 | 10 | −7 | −9 | −13 | 3 | 89 | 199 | 58 | 120 | 5 |
| Example 5 | 0.47 | 8 | 8 | 10 | −9 | −8 | −12 | 2 | 93 | 120 | 55 | 212 | 14 |
| Example 6 | 0.54 | 9 | 8 | 12 | −8 | −12 | −13 | 9 | 40 | 214 | 119 | 191 | 20 |
| Example 7 | 0.52 | 11 | 8 | 11 | −8 | −15 | −17 | 10 | 69 | 243 | 136 | 281 | 35 |
| Example 8 | 0.53 | 11 | 8 | 11 | −8 | −15 | −17 | 8 | 62 | 248 | 129 | 260 | 31 |
| Example 9 | 0.57 | 11 | 8 | 11 | −8 | −15 | −17 | 8 | 65 | 240 | 133 | 277 | 38 |
| Example 10 | 0.47 | 11 | 8 | 11 | −8 | −15 | −17 | 4 | 70 | 238 | 124 | 344 | 59 |
| Example 11 | 0.52 | 10 | 9 | 10 | −9 | −16 | −17 | 9 | 62 | 259 | 136 | 277 | 37 |
| Comparative | 0.77 | 63 | 16 | 18 | −12 | −15 | −24 | 18 | 211 | 621 | 525 | 381 | 89 |
| Example 1 | | | | | | | | | | | | | |
| Comparative | 0.50 | 56 | 17 | 18 | −10 | −15 | −20 | 2 | 165 | 246 | 161 | 289 | 45 |
| Example 2 | | | | | | | | | | | | | |
| Comparative | 0.45 | 25 | 17 | 17 | −6 | −15 | −19 | 2 | 101 | 210 | 131 | 269 | 40 |
| Example 3 | | | | | | | | | | | | | |
| Comparative | 0.66 | 25 | 17 | 18 | −5 | −15 | −19 | 22 | 104 | 349 | 340 | 299 | 61 |
| Example 4 | | | | | | | | | | | | | |
| Comparative | 0.40 | 8 | 8 | 9 | 0 | 0 | 0 | 25 | 767 | 244 | 180 | 423 | 129 |
| Example 5 | | | | | | | | | | | | | |

As is apparent from the above Table 2, it was found that the post-CMP cleaning compositions A1 to A11 of Examples 1 to 11 can reduce residues on the surface of the polished object to be polished containing the silicon-containing material, as compared with the post-CMP cleaning compositions B1 to B5 of Comparative Examples 1 to 5.

What is claimed is:

1. A post-chemical mechanical polishing cleaning composition comprising:
a nitrogen-containing nonionic polymer; and an anionic polymer containing a sulfonic acid group,
wherein a content of the nitrogen-containing nonionic polymer is more than

0. 1% by mass and less than 1.0% by mass with respect to the entire post-chemical mechanical polishing cleaning composition, and
a pH is less than 7.0.

2. The post-chemical mechanical polishing cleaning composition according to claim 1, wherein the nitrogen-containing nonionic polymer has an amide bond.

3. The post-chemical mechanical polishing cleaning composition according to claim 1, wherein a weight-average molecular weight of the nitrogen-containing nonionic polymer is 80,000 or less.

4. The post-chemical mechanical polishing cleaning composition according to claim 1, wherein the nitrogen-containing nonionic polymer comprises at least one selected from the group consisting of polyvinyl pyrrolidone, poly-N-vinylacetamide, polydimethylacrylamide, polyvinyl caprolactam, N-isopropylacrylamide, and an oxazoline group-containing polymer.

5. The post-chemical mechanical polishing cleaning composition according to claim 1, further comprising a chelating agent having 2 or more phosphoric acid groups.

6. The post-chemical mechanical polishing cleaning composition according to claim 1, which is substantially free of an abrasive.

7. A post-chemical mechanical polishing cleaning method for surface-treating a polished object to be polished containing at least one type selected from the group consisting of silicon oxide, polysilicon, and silicon nitride using the post-chemical mechanical polishing cleaning composition according to claim 1, to reduce residues on a surface of the polished object to be polished.

8. The post-chemical mechanical polishing cleaning method according to claim 7, which is a rinse polishing treatment method or a cleaning treatment method.

9. A method for producing a semiconductor substrate, a polished object to be polished being a polished semiconductor substrate, the method comprising:
a polishing step of polishing a pre-polishing semiconductor substrate containing at least one selected from the group consisting of silicon oxide, polysilicon, and silicon nitride using a polishing composition containing an abrasive to provide a polished semiconductor substrate; and
a post-chemical mechanical polishing cleaning step of reducing residues containing the abrasive on a surface of the polished semiconductor substrate using the post-chemical mechanical polishing cleaning composition according to claim 1.
